(19) United States
(12) Patent Application Publication
(10) Pub. No.: US 2006/0055032 A1
(43) Pub. Date: Mar. 16, 2006

(54) Packaging with metal studs formed on solder pads

(76) Inventors: Kuo-Chin Chang, Chia-Yi City (TW); Kuo-Ning Chiang, HsinChu (TW)

Correspondence Address: DUANE MORRIS LLP;IP DEPARTMENT (TSMC), 30 SOUTH 17TH STREET, PHILADELPHIA, PA, 19103-4196, US

(21) Appl. No.: 10/941,586

(22) Filed: Sep. 14, 2004

(51) Int. Cl. H01L 23/48

(52) U.S. Cl. 257/734

(57) ABSTRACT

A semiconductor assembly has solder bumps with increased reliability. One embodiment of an assembly comprises a first substrate having at least one conductive pad on its surface; a second substrate having at least one conductive pad on its surface; at least one conductive stud; and at least one solder bump in contact with the conductive pad on the first substrate, and in contact with the conductive pad of the second substrate, and formed around the at least one conductive stud. Methods for providing these assemblies are included.

### FIELD OF THE INVENTION

The present invention relates to semiconductor assemblies generally, and specifically to flip chip packages and area array packages.

### BACKGROUND

Flip chip technology provides a method for connecting an integrated circuit (IC) die to a substrate within a package. In the flip chip method, a plurality of electrical terminals (pads) are formed on an active face of the die. A respective solder bump is formed on each of the electrical terminals. The package substrate has a plurality of terminal pads corresponding to the terminals on the die. The die is “flipped,” so that the terminals of the device contact the terminal pads of the package substrate. Heat is applied to reflow the solder bumps, forming electrical and mechanical connections between the substrate and the active face of the die. An underfill material is filled into the space between the die and the substrate to strengthen the die/substrate adhesion, redistribute thermal mismatch loading, and protect the solder connections. A plurality of solder bumps are then formed on terminal pads of the package substrate, on the side opposite the die. These bumps can be heated to reflow the solder and form electrical and mechanical connections between the flip chip package and a printed circuit (PC) board, or PCB. Terminal pads are sometimes referred to as “solder pads” or “contact pads” by those skilled in the art.

The underfill operation increases manufacturing assembly time, costs, and makes it difficult to rework the underfilled chip. Additionally, the flip chip package absorbs moisture under humid and hot conditions for an extended period of time resulting in reduced adhesion at interfaces. When the flip chip package with absorbed moisture undergoes solder reflow for attachment to a PCB, high hygrothermal stresses are induced at some locations of already weakened interfaces. These stresses result from coefficient of thermal expansion mismatches between the die and the package substrate, and the expansion of absorbed moisture. These stresses may exceed interfacial strengths causing delamination between the die and the underfill, or at the interface of the underfill with the substrate, or at both interfaces. The delamination forces can induce solder flow from solder bumps, degrading the long term operating reliability of the flip chip package.

If no underfill material is employed, the flip chip solder bumps provide the only adhesion between the die and the substrate and are fully exposed to the thermal induced stresses. Repeated thermal cycling causes the solder bumps to fail (fatigue failure) by loss of adhesion at the interface or formation of stress induced cracks within the solder bump. The reliability of the solder bumps is related to the stress/strain behaviors under cyclical thermal deformation. Reducing the stress/strain on solder bumps improves reliability and increases fatigue life.

U.S. Pat. Nos. 6,716,738 and 6,756,294 further describe the solder bump reliability issue related to crack formation at the interface between the solder pad and the solder bump. The solder pad typically comprises copper or aluminum metal. A UBM (Under Bump Metallurgy) layer is bonded to the pad, and then bonded to a conductive solder bump. The UBM layer typically comprises a plurality of thin layers of other metals (metallization) for adhesion, wetting, and protection. Typically the UBM adhesion layer is applied to the pad surface and may comprise Chromium, or Titanium. Subsequently the UBM wetting layer is applied on top of the UBM adhesion layer to increase bondability and wettability of the solder. Typically, the UBM wetting layer comprises nickel, or copper. A thin layer of gold is typically applied to the UBM wetting layer to provide protection from oxidation.

When the solder bump is applied to the pad and also later reflowed, The UBM can not stop molecular diffusion between the solder and the pad. Additionally, diffusion continues over time and with repeated thermal cycling. This leads to the formation of molecular layers of intermetallic compounds adjacent the solder/pad interface. These intermetallic compound layers are significantly weaker than the solder, and stress cracks are more easily formed and propagated within these layers. This problem is a concern within a flip chip package and packages mounted on a PCB.

Therefore, a more reliable method of using solder bumps for electrical and mechanical connections is desired.

### SUMMARY OF THE INVENTION

In some embodiments, an assembly comprises a first substrate having at least one conductive pad on a surface thereof, a second substrate having at least one conductive pad on a surface thereof, at least one conductive stud on the conductive pad of at least one of the first and second substrates, and at least one solder bump in contact with the conductive pad on the first substrate, and in contact with the conductive pad of the second substrate, and formed around the at least one conductive stud.

In some embodiments, a package comprises: a package substrate having a die on one surface and at least one conductive pad on a second surface opposite the first surface, at least one conductive stud on the conductive pad, and at least one solder bump in contact with said conductive pad and formed around said at least one conductive stud.

In some embodiments, a method comprises providing a die having at least one conductive pad on an active surface thereof, forming a conductive stud on the conductive pad, and forming a solder bump around the conductive stud.

In some embodiments, a method comprises providing a first substrate having at least one conductive pad on a surface thereof, forming at least one conductive stud on a portion of the conductive pad of the first substrate, applying a solder bump onto at least a portion of the conductive pad of the first substrate around the conductive stud, placing the solder bump in contact with a conductive pad of a second substrate, and reflowing the solder bump, thereby forming electrical and mechanical connections between the first and the second substrates while maintaining the conductive stud therebetween.

### BRIEF DESCRIPTION OF THE DRAWINGS

FIGS. 1A and 1B are each a cross-sectional view of an embodiment of an assembly of the present invention.

FIG. 2 is a cross-sectional view of another embodiment of an assembly of the present invention.

FIGS. 3A and 3B are each a cross-sectional view of an embodiment of a flip chip assembly of the present invention.

FIG. 4 is a cross-sectional view of another embodiment of a flip chip assembly of the present invention.

FIGS. 5A and 5B are each a cross-sectional view of an embodiment of an assembly including a package mounted to a printed circuit board.

FIG. 6 is a cross-sectional view of another embodiment of an assembly including a package mounted to a printed circuit board.

FIG. 7A is an isometric view of the conductive studs of the present invention having a cross or circular (shown in FIG. 7B) shape.

FIGS. 7B-7D are cross-sectional views of a single conductive stud, two conductive studs, or three conductive studs formed on a single conductive pad.

FIGS. 8A-8E show an exemplary method of providing an integrated circuit die having at least one conductive stud on a surface of at least one conductive pad, and including a solder bump formed around the at least one conductive stud and attached to the at least one conductive pad.

FIG. 9 is a table showing the number of fatigue life cycles for the structure corresponding to FIG. 4 verses the height and radius of circular shaped copper conductive studs in one experiment.

FIG. 10 is a table showing the number of fatigue life cycles for the structure corresponding to FIG. 4 verses the height and edge length of cross shaped copper conductive studs in the experiment.

FIG. 11 is a graph showing the effect of height and radius of a circular shaped copper conductive stud attached to a conductive pad on solder bump shear strength.

FIG. 12 is a graph showing the effect of height and edge length of a cross shaped copper conductive stud attached to a conductive pad on solder bump shear strength.

### DETAILED DESCRIPTION

This description of the exemplary embodiments is intended to be read in connection with the accompanying drawings, which are to be considered part of the entire written description. In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise. Like reference numerals appearing in multiple figures indicate like elements.

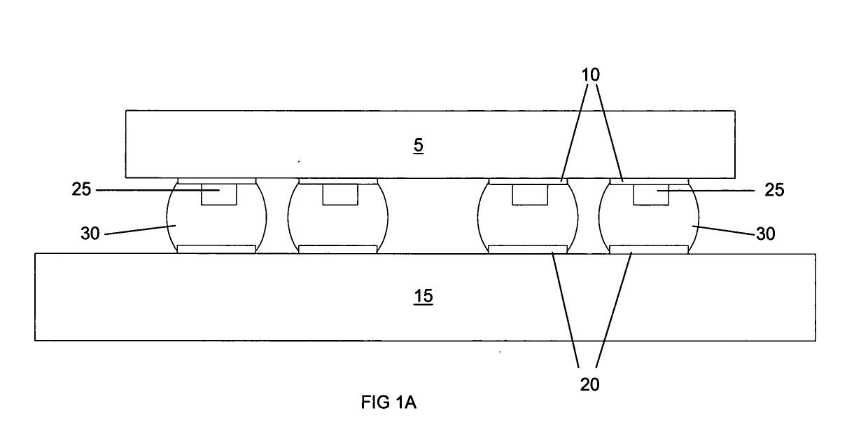

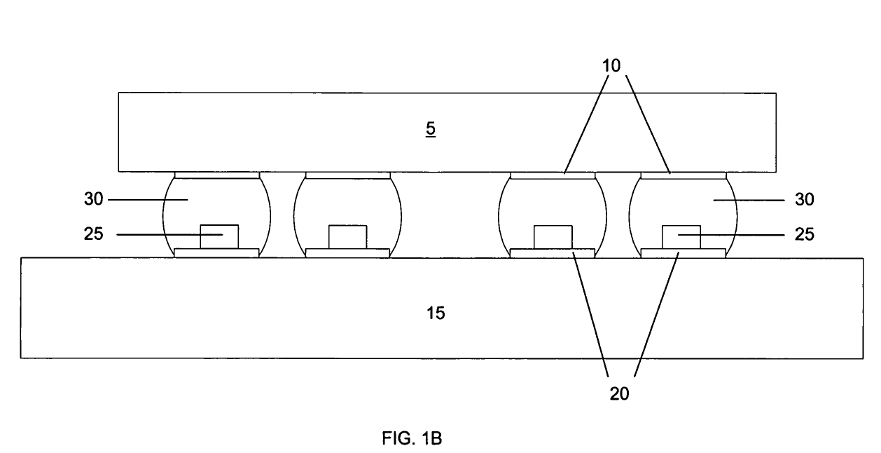

FIGS. 1A and 1B each show an assembly comprising a first substrate 5 having at least one conductive pad 10 on a surface thereof, a second substrate 15 having at least one conductive pad 20 on a surface thereof, and at least one conductive stud 25 embedded in the solder bump 30, which is formed on the conductive pad 10 or 20. After the first substrate is mounted to the second substrate, the solder bump 30 is in contact with the conductive pad 10 on the first substrate 5, and in contact with the conductive pad 20 of the second substrate 15, and contains the at least one conductive stud 25.

The stud(s) 25 reinforces the mechanical solder connection between the first substrate 5 and the second substrate 15, to resist delamination during thermal cycling.

The first substrate 5 and second substrate 15 may be any substrate, including, for example, those suitable for use as an integrated circuit die substrate, a package substrate or a PCB. Examples of such substrates include, but are not limited to, ceramic, glass, polymer, a semiconductor material. In FIG. 1A, the stud 25 is formed on the conductive pad 10 of the first substrate, which is mounted on the second substrate; the first substrate may be, for example, an integrated circuit die. In FIG. 1B, the stud 25 is formed on the conductive pad 20 of the second substrate, to which the first substrate is mounted. The second substrate may be, for example, a package substrate.

In FIG. 1A, the stud 25 is contained within the solder bump 30. The reflow step may be performed without applying pressure to the first substrate 5, so that a solder-filled space is maintained between the stud 25 and the conductive pad 20 of the second substrate 15. Alternatively, one or more spacers (not shown) may be inserted between the first and second substrates 5 and 15 to ensure that the solder bumps 30 are not crushed, and short circuiting is avoided. Similarly, in FIG. 1B, the reflow step may be performed without applying pressure to the first substrate 5, so that a solder-filled space is maintained between the stud 25 and the conductive pad 10 of the first substrate 5; or a spacer may be used

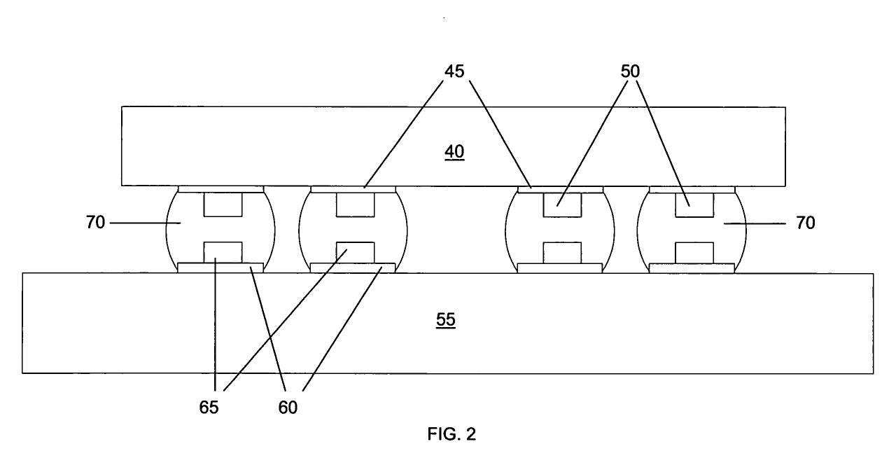

In FIG. 2, the pads of both the first and second substrates have studs thereon. FIG. 2 shows an assembly comprising a first substrate 40 having at least one conductive pad 45 on a surface thereof, and at least one conductive stud 50 attached to the conductive pad 45. The assembly includes a second substrate 55 having at least one second conductive pad 60 on a surface thereof, and at least one conductive stud 65 attached to the conductive pad 60. The assembly further includes at least one solder bump 70 formed around either one of the at least one conductive stud 50 or the at least one conductive stud 65, and reflowed around the other one of the studs 50 or 65. Preferably, the solder bumps 70 are formed around the studs 50 of the first substrate 40, which is mounted on the second substrate 55.

As described above, the reflow step of FIG. 2 may be performed without applying pressure to the first substrate 40, so that a solder-filled space is maintained between the studs 50 and 65. Alternatively, one or more spacers (not shown) may be inserted between the first and second substrates 40 and 55 to ensure that the solder bumps 70 are not crushed, and short circuiting is avoided.

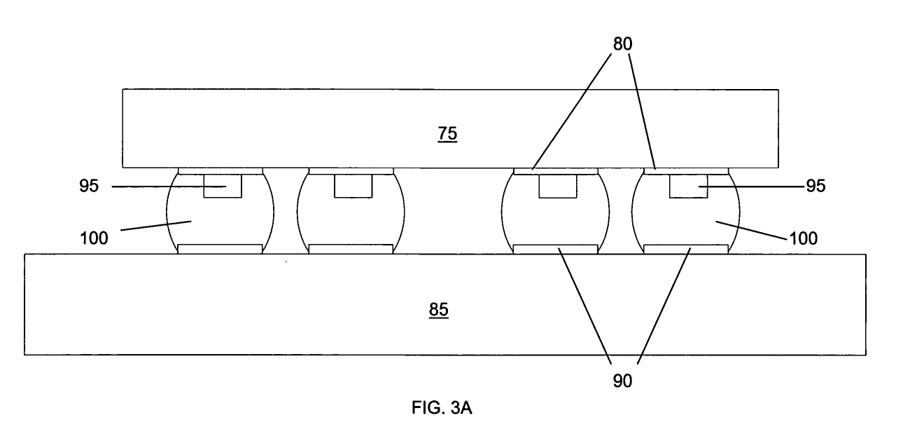

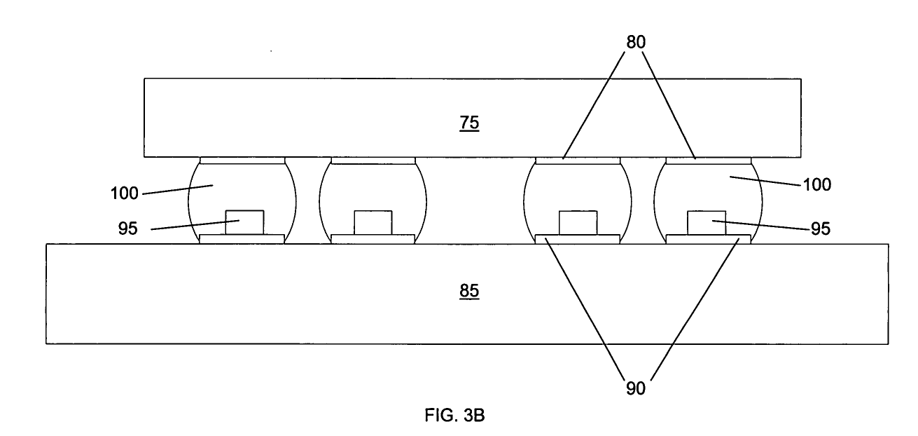

In FIGS. 3A, 3B and 4, the first substrate is an IC die, and the second substrate is a package substrate. FIGS. 3A and 3B each show a flip chip assembly comprising a die 75 having at least one conductive pad 80 on a surface thereof, a substrate 85 having at least one conductive pad 90 on a surface thereof, and at least one conductive stud 95. The assembly includes at least one conductive bump 100 in contact with the conductive pad 80 on die 75, and in contact with the conductive pad 90 on substrate 85, and formed around the at least on conductive stud 95. The use of the stud 95 allows the flip-chip assembly to be made without an underfill, while still providing strong mechanical connections and resisting solder ball delamination. The stud(s) 25 enhances the solder bump reliability of the flip chip packaging, and is particularly advantageous in a package without the underfill. When an intermetallic compound layer forms at the solder/pad interface, the metal stud should stop the crack propagation or lengthen the crack path.

FIG. 4 shows a flip chip assembly comprising a die 105 having at least one conductive pad 110 on a surface thereof, and at least one conductive stud 115 attached to the conductive pad 110. The assembly includes a package substrate 120 having at least one conductive pad 125 on a surface thereof, and at least one conductive stud 130 attached to the conductive pad 125 on package substrate 120. At least one solder bump 135 contacts conductive pads 110 and 125 and is formed around either the at least one conductive stud 115 or the at least one conductive stud 130. Preferably, the solder bump 135 is formed around the stud 115 of the die 105, and reflowed to encapsulate studs 115 and 130.

As in the case of the flip-chip assembly shown in FIGS. 3A and 3B, the assembly of FIG. 4 provides a reliable mechanical interconnection between the die 105 and package substrate 120 that is resistant to delamination during thermal cycling, without requiring an underfill.

One of ordinary skill in the art will understand that the stud(s) 25 may also be used in a flip-chip package having an underfill, to provide even greater mechanical reliability and resistance to delamination.

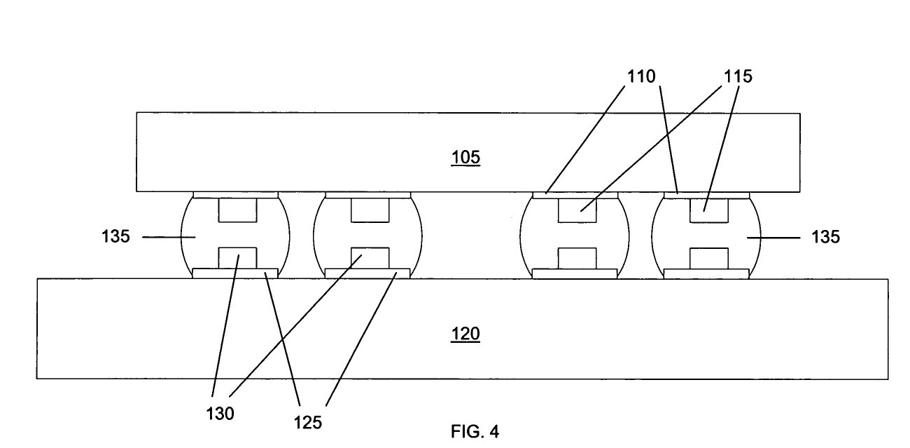

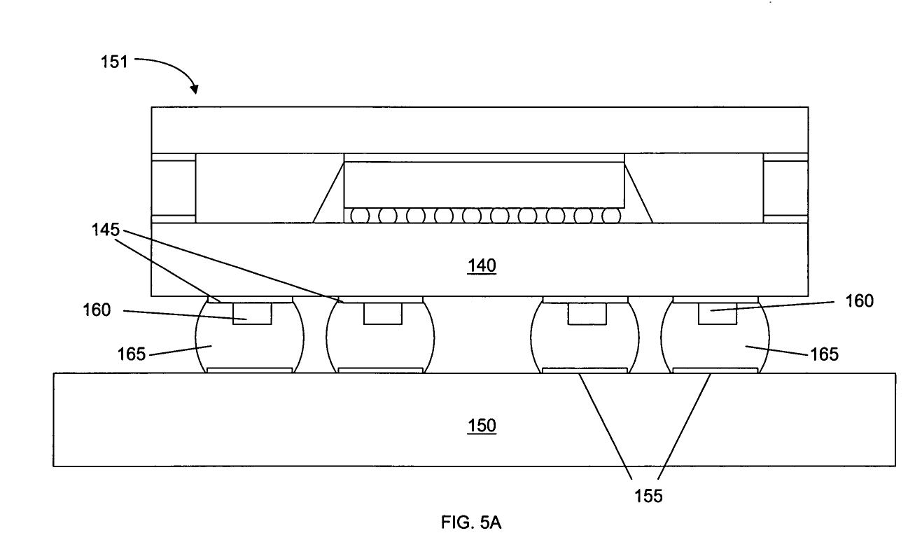

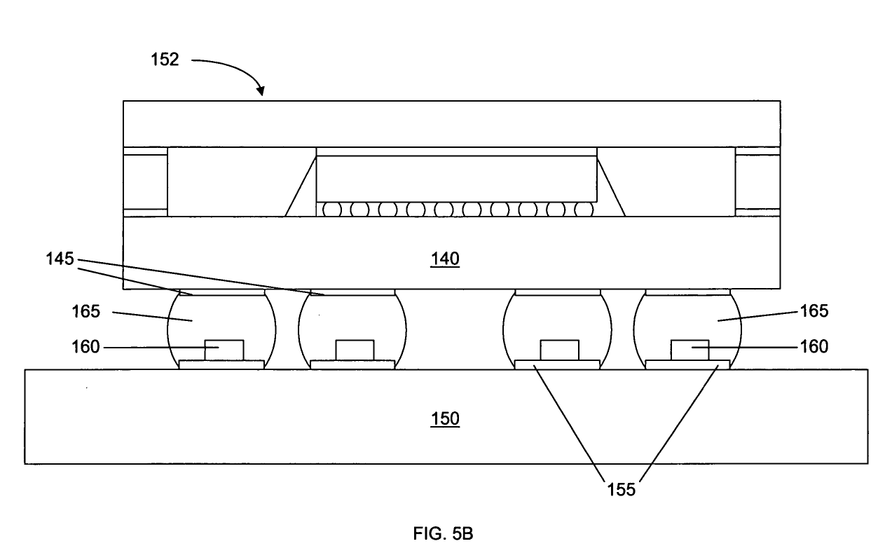

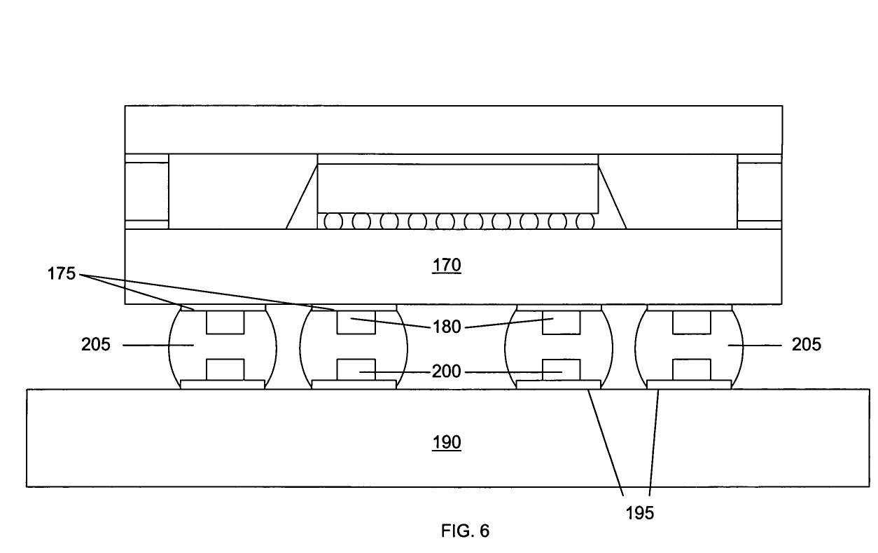

In FIGS. 5A, 5B and 6, the first substrate is a package substrate of an IC package, and the second substrate is a PCB to which the package is mounted. FIGS. 5A and 5B each show an assembly comprising a printed circuit board 150 to which an area array package 151 has been attached. The exemplary package 151 shown is a flip chip package, but other area array packages can be mounted using the same technique. The assembly comprises a package substrate 140 having at least one conductive pad 145 on a surface thereof, a printed circuit board 150 having at least one conductive pad 155 on a surface thereof, and at least one conductive stud 160. The assembly further includes at least one solder bump 165 in contact with conductive pad 145 on package substrate 140, and in contact with conductive pad 155 on printed circuit board 150, and formed around conductive stud 160.

In one embodiment (FIG. 5A), the package 151 comprises: a package substrate 140 having a die on one surface and at least one conductive pad 145 on a second surface opposite the first surface, at least one conductive stud 160 on the conductive pad 145; and at least one solder bump 165 formed around the conductive stud 160 in contact with the conductive pad 145. The package 151 is connected to the PCB 150 by reflowing the solder bump(s) 165.

In one embodiment (FIG. 5B), the studs 160 are formed on the conductive pads 155 of the PCB 150, and an area array package 152 (which may be a conventional area array package or other area array package) is connected to the PCB 150.

FIG. 6 shows an assembly of a package and a printed circuit board. The package may be a package of the type shown in FIG. 5A, having studs 180 on the conductive pads 175, and encapsulated by solder bumps 205. The PCB 190 may be a PCB of the type shown in FIG. 5B, with studs 200 on the conductive pads 195. The assembly comprises a package with a package substrate 170 having at least one conductive pad 175 on a surface thereof, and at least one conductive stud 180 attached to the at least one conductive pad 175 on package substrate 170. The assembly includes a PCB substrate 190 having at least one conductive pad 195 on a surface thereof, and at least one conductive stud 200 attached to the at least one conductive pad 195. The at least one solder bump 205 is formed around conductive stud 180 and reflowed around conductive stud 200 so as to contact conductive pads 175 and 195.

The conductive stud preferably comprises a conductive material that is harder than the solder bump composition. Preferred materials include, but are not limited to, copper, aluminum or gold.

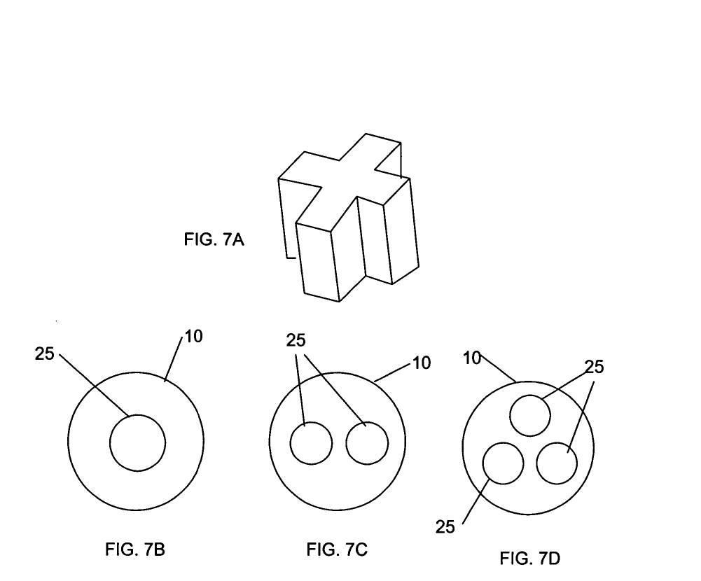

Referring to FIGS. 7A and 7B, the conductive stud can have as a cross section any of a variety of shapes, including, but not limited to a cross as shown in FIG. 7A or a circle, as shown in FIG. 7B. However, other cross section shapes (not shown) may be employed, including, but not limited to a square, rectangle, rhombus, ellipse, or polygon. Additionally, more than one conductive stud can be attached to a conductive pad as shown in FIGS. 7C and 7D. In FIG. 7C, two studs 25 are formed on one conductive pad 10. In FIG. 7D, three studs 25 are formed on one conductive pad 10. Furthermore, the cross sectional area and length of the conductive stud can be varied as described below, since these variables can influence improved reliability performance.

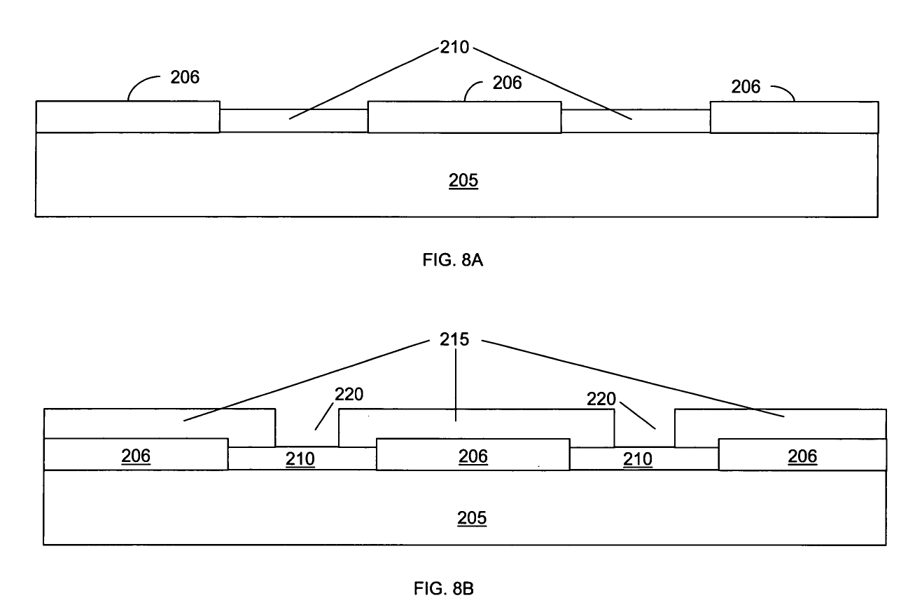

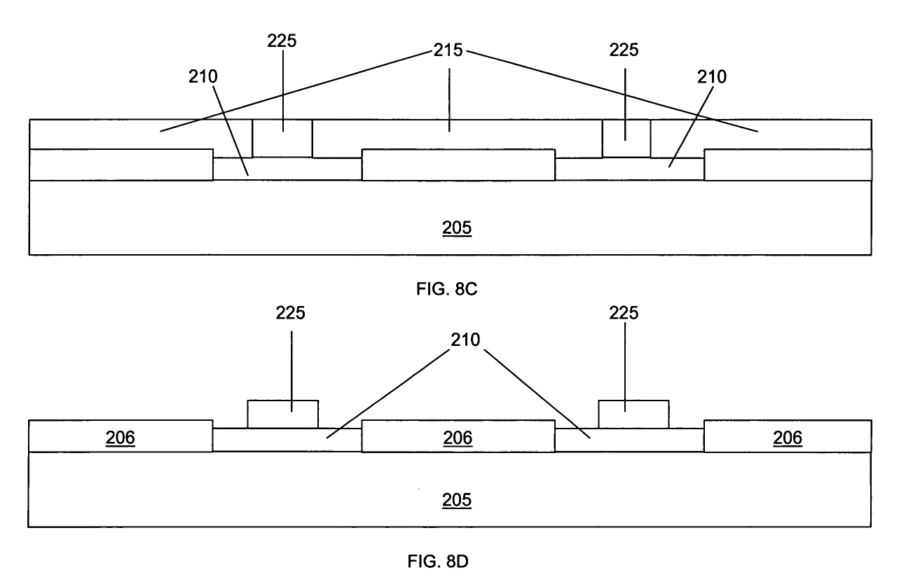

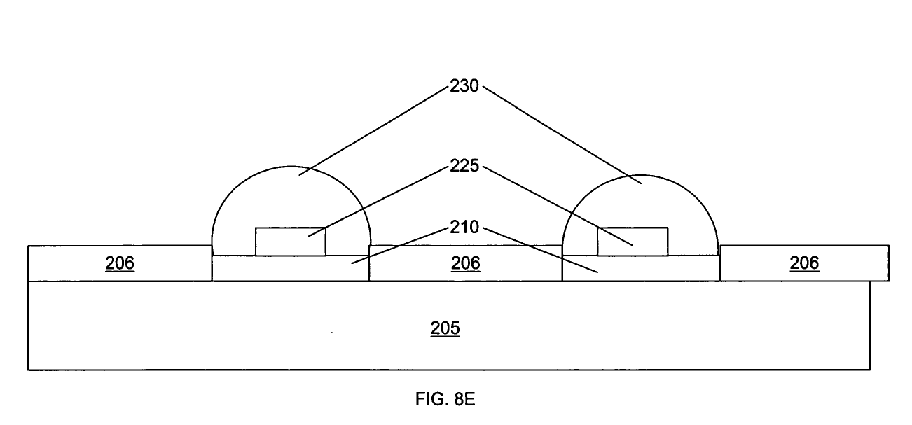

FIGS. 8A to 8E show one preferred method of making a conductive stud attached to a conductive pad on a substrate. In FIG. 8A, the substrate 205 is an integrated circuit die having a solder mask (solder resist) 206 thereover, except for at least one opening in the solder mask 206 having at least one conductive pad 210 in the opening, on the surface of the substrate 205. The solder mask may be formed of a liquid or dry film type, for example. Liquid solder resist masks may be applied by screen printing or the like. The solder mask may be formed of an organic compound such as an epoxy resin. For example, the solder resist may be a thermosetting resin that is cured by heating after it is deposited. Solder resist materials having C—C, C—O, C—H and/or C—Si bonds may be used. A solder mask may be formed using the method of U.S. Pat. No. 5,626,774 or U.S. Pat. No. 6,346,678, both of which are expressly incorporated by reference herein in their entireties.

FIG. 8B shows a mask 215 overlying the solder mask 206 and at least a portion of conductive pad(s) 210. The mask 215 includes an open area 220 for forming the stud. The mask 215 can be patterned to provide any desired cross section shape to the opening 220. Any mask composition can be employed for mask 215, as long as it is compatible with the substrate and the deposition process. The mask 215 may be applied using a photolithographic process, for example. Alternatively, the mask layer 215 can be made of a material such as silicon oxide, silicon nitride or silicon oxy-nitride. The mask layer 215 can be formed, for example, by CVD with dichlorosilane (SiCl2H2) and ammonia (NH3) as reaction gases.

FIG. 8C shows a conductive material deposited within the opening 220 to create the conductive stud 225. The amount of deposition and thickness of the mask 215 can be used to control the thickness (height) of the conductive stud 225 formed. One preferred method of depositing a conductive material is electroplating, and one preferred conductive material is copper. Alternatively, chemical vapor deposition (CVD) may be used.

FIG. 8D shows the resultant at least one conductive stud 225 attached to the conductive pads 210 after removal of the mask 215. If the mask 215 is a photoresist, the mask can be removed by a conventional ashing process.

FIG. 8E shows the formation of a solder bump 230 around the conductive stud 225 attached to conductive pad 210. The step of forming a bump on the stud can be achieved using conventional methods of applying a bump to a flat pad, including the electroplating, screen printing and ball mount.

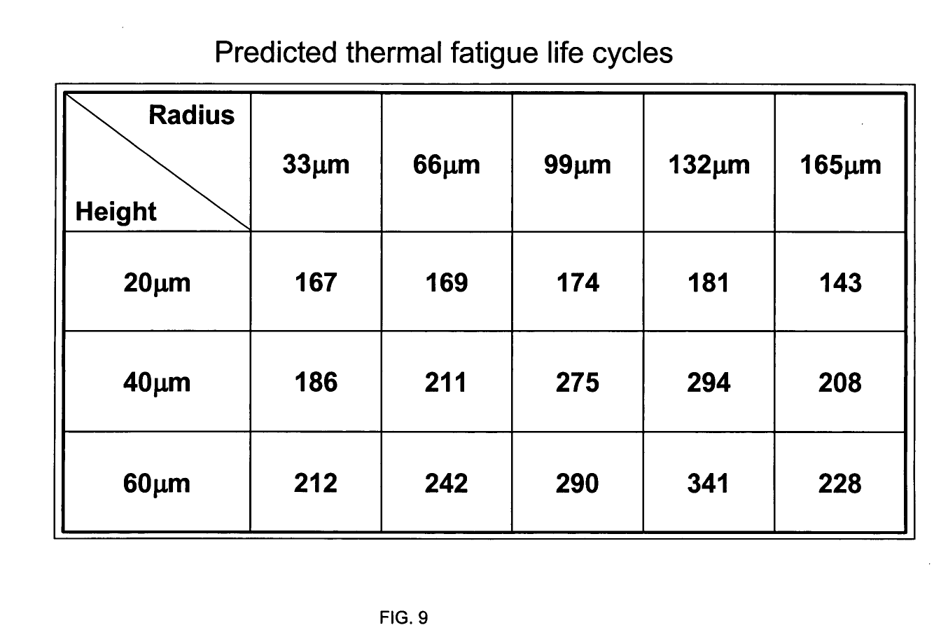

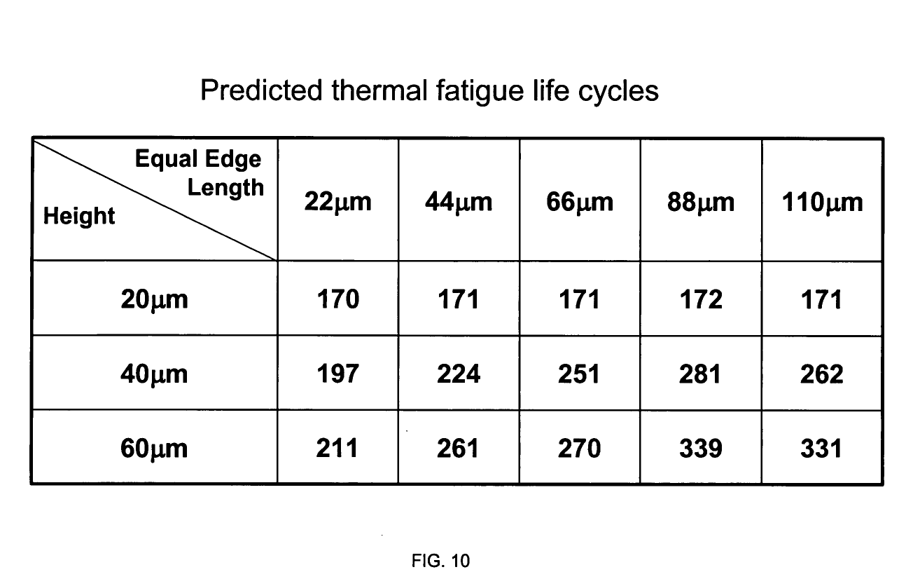

Solder bump reliability of the flip chip assembly of FIG. 4 using copper as the conductive studs 115 and 130 was evaluated without an underfill material. Finite element analysis was used to determine thermal fatigue life cycles of two structures of the type shown in FIG. 4. The first structure utilized copper studs having a circular shape on circular conductive pads. The second structure utilized copper studs having a cross shape (all edges the same length) on circular conductive pads. FIG. 9 shows the thermal fatigue life cycles verses the height of the copper stud and the circular stud radius of the first structure. FIG. 10 shows the thermal fatigue life cycles verses height of the copper studs and edge length of the second structure. Both results show that introducing appropriately sized conductive studs to solder bumps significantly enhances thermal fatigue life of the flip chip assembly. This improved reliability provides an opportunity to utilize flip chip assemblies without underfill material, without risk of delamination during thermal cycling.

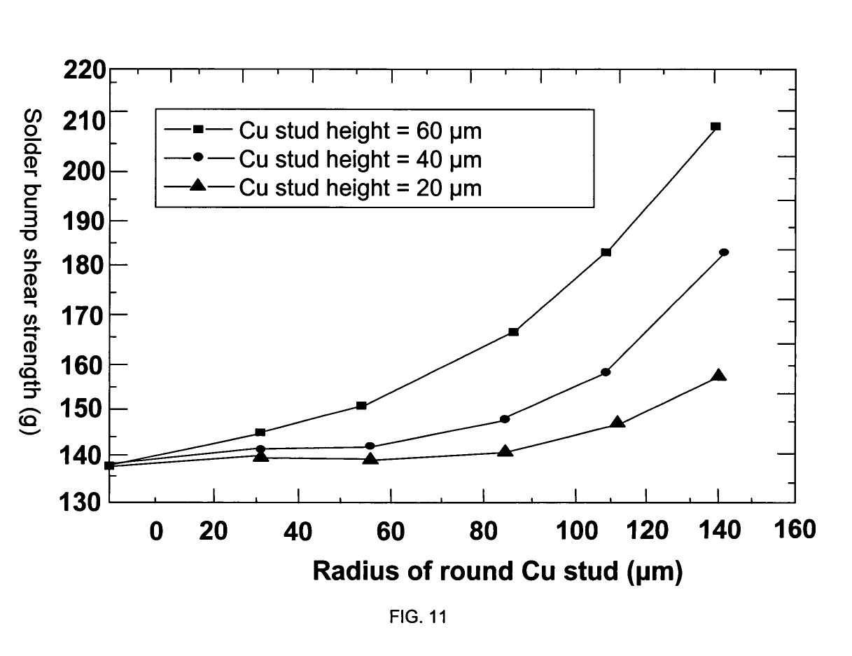

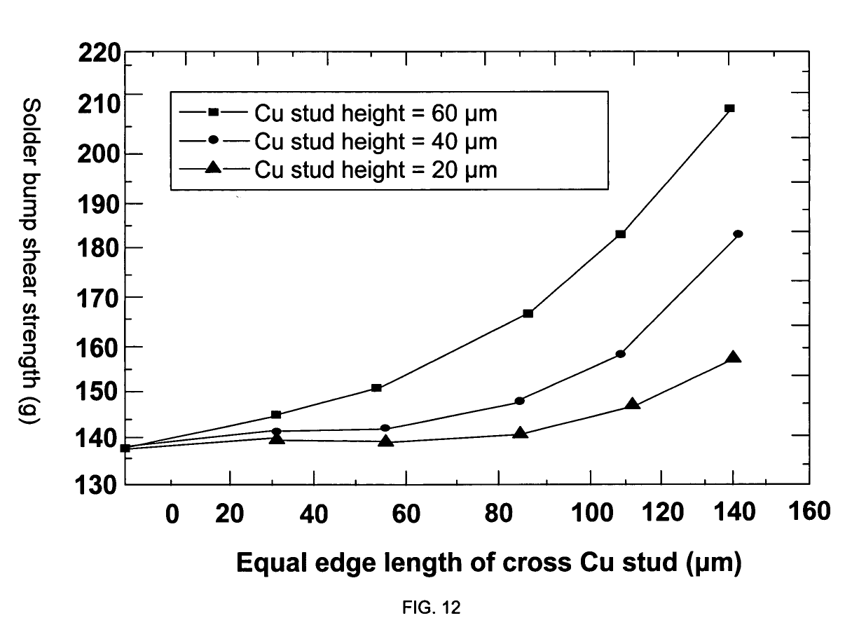

Another significant reliability issue relates to the formation of intermetallic compounds near the solder bump and conductive pad interface which causes weakening and crack formation. This is a particular issue for the solder bumps between Printed Circuit Boards and mounted packages. Well known solder bump/ball shear testing methods have been used to determine solder bump/ball shear strength and document this issue. A finite element analysis of solder bump shear strength was conducted to determine the effect of the conductive stud attached to a circular conductive pad on solder bump shear strength. FIG. 11 is a graph showing the effect on solder bump shear strength of the height and radius of a circular copper stud attached to the conductive pad of a PC board. FIG. 12 is a graph showing the effect of the height and edge length of a cross shaped copper stud on solder bump shear strength. Both results indicate that introducing appropriately sized conductive studs to the solder bumps significantly enhances solder bump shear strength.

Although the invention has been described in terms of exemplary embodiments, it is not limited thereto. Rather, the appended claims should be construed broadly, to include other variants and embodiments of the invention, which may be made by those skilled in the art without departing from the scope and range of equivalents of the invention.

1. An assembly comprising:
a first substrate having at least one conductive pad on a surface thereof;
a second substrate having at least one conductive pad on a surface thereof;
a first conductive stud attached to said conductive pad of said first substrate and a second conductive stud attached to said conductive pad of said second substrate,
at least one solder bump in contact with said conductive pad on said first substrate, and in contact with said conductive pad of said second substrate, the solder bump formed around one of the group consisting of said first conductive stud and said second conductive stud.

2. (canceled)

3. The assembly of claim 1, wherein said first substrate is a semiconductor die.

4. The assembly of claim 3, wherein said assembly is a flip chip package, and said second substrate is a package substrate thereof.

5. (canceled)

6. The assembly of claim 32 wherein said first substrate is a package substrate of an area array package.

7. The assembly of claim 32, wherein said first substrate is a package substrate of a flip chip package.

8. The assembly of claim 32, wherein said at least one conductive stud has a shape from the group consisting of a circle, square, cross, rectangle, rhombus, ellipse, and polygon.

9. (canceled)

10. The assembly of claim 33, wherein said at least two conductive studs have the same geometric shape.

11. The assembly of claim 32, wherein said at least one conductive stud is made of a material that is harder than said solder bump.

12. The assembly of claim 11, wherein said material includes copper, aluminum, or gold.

13. The assembly of claim 32, wherein said at least one conductive stud has a height from about 5 microns to about 60 microns.

14. The assembly of claim 32, wherein said at least one conductive stud has a cross-section width from about 10 microns to about 100 microns.

15. A package comprising:
a package substrate having a die on one surface and at least one conductive pad on a second surface opposite the first surface;
at least one conductive stud on the conductive pad; and
at least one solder bump in contact with said conductive pad, and formed around said at least one conductive stud.

16. The package of claim 15, wherein said at least one conductive stud has a shape from the group consisting of a circle, square, cross, rectangle, rhombus, ellipse, and polygon.

17. The package of claim 15, wherein said at least one conductive stud is made of a material that is harder than said solder bump.

18. The package of claim 17, wherein said material includes copper, aluminum, or gold.

19. A substrate comprising:
at least one surface having at least one conductive pad thereon;
at least two conductive studs on said conductive pad; and
at least one solder bump in contact with said at least one conductive pad and formed around said at least two conductive studs.

20. The substrate of claim 19, wherein said at least two conductive studs have a shape from the group consisting of a circle, square, cross, rectangle, rhombus, ellipse, and polygon.

21. The substrate of claim 19, wherein said at least two conductive studs are made of a material that is harder than said solder bump

22. The substrate of claim 21, wherein said material includes copper, aluminum, or gold.

23. A method comprising:
providing a die having at least one conductive pad on an active surface thereof;
forming at least two conductive studs on said conductive pad; and
forming a solder bump around the conductive studs.

24. The method of claim 23, further comprising forming a mask overlying the die and having a pattern therein, wherein the conductive studs are formed using the mask.

25. The method of claim 24, wherein said conductive studs are formed by electroplating.

26. A method comprising:
providing a first substrate having at least one conductive pad on a surface thereof;
forming at least two conductive studs on a portion of said conductive pad of said first substrate; and
applying a solder bump onto at least a portion of said conductive pad of said first substrate around said conductive studs.

27. The method of claim 26 further comprising placing said solder bump in contact with a conductive pad of a second substrate, and reflowing said solder bump, thereby forming electrical and mechanical connections between said first and said second substrates while maintaining said conductive studs therebetween.

28. (canceled)

29. The method of claim 27, wherein said method provides a flip chip package.

30. The method of claim 27, wherein said method provides an area array package.

31. The method of claim 27, wherein said method provides a package bonded to a printed circuit board.

32. An assembly comprising:
a first substrate having at least one conductive pad on a surface thereof;
a printed circuit board having at least one conductive pad on a surface thereof;
at least one conductive stud on the conductive pad of at least one of the first substrate and the printed circuit board; and
at least one solder bump in contact with said conductive pad on said first substrate, and in contact with said conductive pad of said printed circuit board, the solder bump formed around 8 said at least one conductive stud.

33. An assembly comprising:
a first substrate having at least one conductive pad on a surface thereof;
a second substrate having at least one conductive pad on a surface thereof;
at least two conductive studs on the conductive pad of at least one of the first and second substrates; and
at least one solder bump in contact with said conductive pad on said first substrate, and in contact with said conductive pad of said second substrate, the solder bump formed around said at least two conductive studs.

34. A method comprising:
providing a first substrate and a second substrate, each having at least one conductive pad on a surface thereof;
forming at least one conductive stud on a portion of said conductive pad of said first substrate and at least one conductive stud on a portion of said conductive pad of said second substrate;
applying a solder bump onto at least a portion of said conductive pad of said first substrate around said conductive stud thereof;
placing said solder bump in contact with the at least one conductive stud attached to the conductive pad of the second substrate; and
reflowing said solder bump, thereby forming electrical and mechanical connections between said first and said second substrates while maintaining said conductive studs therebetween.

35. A method comprising:
providing a package substrate of a package, having at least one conductive pad on a surface thereof;
forming at least one conductive stud on a portion of said conductive pad of said package substrate;
applying a solder bump onto at least a portion of said conductive pad of said package substrate around said conductive stud;
placing said solder bump in contact with a conductive pad of a printed circuit board, and
reflowing said solder bump, thereby forming electrical and mechanical connections between said package substrate and said printed circuit board while maintaining said conductive stud therebetween.
